(19) United States
(12) Patent Application Publication
(10) Pub. No.: US 2002/0014680 A1
(43) Pub. Date: Feb. 7, 2002

(54) Semiconductor device and method of manufacturing the same

(75) Inventor: Isao Tottori, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Chiyoda-ku (JP)

(21) Appl. No.: 09/827,892

(22) Filed: Apr. 9, 2001

(30) Foreign Application Priority Data
Jul. 28, 2000 (JP) 2000-228265

(51) Int. Cl. H01L 21/82

(52) U.S. Cl. 257/529; 438/132

(57) ABSTRACT

Provided is a semiconductor device comprising a fuse for switching connections to a redundant circuit, which is capable of improving arrangement flexibility of the fuse and achieving an increase in the degree of integration.

A third interlayer insulation film (23) is provided so as to cover a second interconnection layer (10), and a plurality of contact portions (12) are provided which extend through the third interlayer insulation film (23) to reach the second interconnection layer (10). The contact portions (12) have a structure in which via holes extending through the third interlayer insulation film (23) are filled with a refractory metal such as tungsten. A fuse (13) is provided between two of the contact portions (12) in the third interlayer insulation film (23) so as to be electrically connected to the two of the contact portions (12). The fuse (13) is made of the same refractory metal as the contact portions (12).

### BACKGROUND OF THE INVENTION

1. Field of the Invention

The present invention relates to a semiconductor device and a method of manufacturing the same, and more particularly to a semiconductor device comprising a fuse for switching connections to a redundant circuit and a method of manufacturing the same.

2. Description of the Background Art

In a recent semiconductor device of large capacity, it is technically difficult to manufacture all memory cells constituting a memory portion without problems so that they operate normally. If a failure memory cell is found at a manufacturing stage, memory arrays of the number estimated by the rate of occurrence of failure are prepared as redundant circuits so that a memory array (column array and row array) including the failure memory cell can be replaced with a spare memory array provided beforehand.

This prevents a semiconductor device itself from being a failure product and allows increase in a manufacturing yield of the semiconductor device.

A fuse has a structure for switching connections from the memory array including the failure memory cell to a spare memory array. Generally, a row decoder and a column decoder of a peripheral circuit portion are constructed in such a manner that the memory array including the failure memory cell cannot be selected and the spare memory array can be selected by fusion of the fuse.

FIG. 11 shows a structure of a peripheral circuit portion of a conventional semiconductor device 90 having the above-described fuse.

Referring to FIG. 11, a plurality of MOS transistors MT are provided on a semiconductor substrate 1. The MOS transistors MT are provided in active regions defined as regions of the semiconductor substrate 1 surrounded by isolation films 2, respectively. Each of the MOS transistors MT comprises: a gate electrode 3 including a gate insulation film 31, a polysilicon layer 32, a silicide layer 33, an upper insulation film 34 which are selectively laminated on the semiconductor substrate 1 in this order and a sidewall insulation film 35 provided on side surfaces of the layers 31, 32, 33 and 34; source/drain region 5 formed in a surface of a well region 4 which is located outside both side surfaces of the gate electrode 3; and an LDD (lightly doped drain) region 6.

A first interlayer insulation film 21 is provided so as to entirely cover a main surface of the semiconductor substrate 1, and a plurality of contact portions 7 each extending through the first interlayer insulation film 21 to reach the source/drain region 5 are provided. The contact portions 7 have a structure in which a contact hall extending through the first interlayer insulation film 21 is filled with a refractory metal such as tungsten.

First interconnection layers 8 composed of aluminum are selectively provided on the first interlayer insulation film 21, and the contact portions 7 are connected to a predetermined one of the first interconnection layers 8, respectively.

A second interlayer insulation film 22 is provided so as to cover the first interconnection layers 8, and contact portions 9 are provided which extend through the second interlayer insulation film 22 to reach the first interconnection layers 8. The contact portions 9 have a structure in which via halls extending through the second interlayer insulation film 22 are filled with a refractory metal such as tungsten.

Second interconnection layers 10 composed of aluminum are selectively provided on the second interlayer insulation film 22, and the contact portions 9 are connected to a predetermined one of the second interconnection layers 10, respectively.

A third interlayer insulation film 23 is provided so as to cover the second interconnection layers 10, and a plurality of contact portions 12 are provided which extend through the third interlayer insulation film 23 to reach the second interconnection layers 10. The contact portions 12 have a structure in which via halls extending through the third interlayer insulation film 23 are filled with a refractory metal such as tungsten.

Third interconnection layers 14 composed of aluminum are selectively provided and a laser-fused fuse 19 is provided on the third interlayer insulation film 23. Some of the contact portions 12 are connected to a predetermined one of the third interconnection layers 14, respectively, and others are connected to the laser-fused fuse 19.

Since the laser-fused fuse 19 effectively absorbs laser light, it cannot be miniaturized excessively compared to a spot diameter of laser light, and thus, its width is set to be 1 to 2 μm and its length is set to be approximately 30 μm.

There is only one laser-fused fuse 19 shown in FIG. 11, however, it is needless to say that a plurality of fuses are provided corresponding to the number of spare memory arrays. A plurality of laser-fused fuses 19 are intensively arranged in parallel to one another and spaced at predetermined intervals (3 to 4 μm) in such a manner that an irradiation position of laser light needs not be moved greatly.

A fourth interlayer insulation film 24, which is the uppermost layer, is provided so as to cover the third interconnection layers 14 and the laser-fused fuse 19, and a contact portion 15 is provided which extends through the fourth interlayer insulation film 24 to reach the third interconnection layers 14. The contact portion 15 has a structure in which a via hall extending through the fourth interlayer insulation film 24 is filled with a refractory metal such as tungsten.

A fourth interconnection layer 16 composed of aluminum is selectively provided on the fourth interlayer insulation film 24. The contact portion 15 is connected to the fourth interconnection layer 16.

Although illustration of the structure of the memory portion is omitted in FIG. 11, either of the interconnection layers included in the peripheral circuit portion is connected to the memory portion.

As described above, the conventional semiconductor device 90 comprises the laser-fused fuse 19. If a failure memory cell is found in a test at a manufacturing stage, laser light is irradiated to fuse the laser-fused fuse 19 related to selection of a memory array including the failure memory cell, and a spare memory array is used instead of the memory array including the failure memory cell.

Therefore, the laser-fused fuse 19 is generally provided on the uppermost interlayer insulation film or an interlayer insulation film next to the uppermost layer considering the convenience for irradiation of laser light. In addition, a plurality of laser-fused fuses 19 are intensively provided in such a manner that an irradiation point of laser light needs not be moved greatly. In this way, the laser-fused fuses are arranged at limited positions.

Further, at the fusion by laser light, laser light that the laser-fused fuse 19 cannot absorb and laser light passing through the laser-fused fuse 19 after the fusion might damage interconnection layers of a multilayered structure provided below the laser-fused fuse 19 and, in some instances, might reach the top of the semiconductor substrate 1 and damage a semiconductor element. A semiconductor device itself is thus likely to be a failure product.

Accordingly, interconnection layers cannot be provided on an interlayer insulation film below the laser-fused fuse 19, and a semiconductor element cannot be provided on the semiconductor substrate 1 below the laser-fused fuse 19. This results in a problem that the degree of integration of the semiconductor device cannot be improved.

### SUMMARY OF THE INVENTION

According to a first aspect of the present invention, a semiconductor device comprises: a semiconductor substrate; a multilevel interconnection layer provided on the semiconductor substrate; an interlayer insulation film provided between a lower interconnection layer and an upper interconnection layer in the multilevel interconnection layer; first and second contact portions extending through the interlayer insulation film and electrically connecting the lower interconnection layer and the upper interconnection layer; and a fuse interposed between the first and second contact portions and provided in a surface of the interlayer insulation film so as to be electrically connected to the first and second contact portions, the fuse being composed of a conductor made of the same material as the first and second contact portions which differs from a material of the upper interconnection layer, the fuse being fusible by flowing overcurrent between the first and second contact portions.

Preferably, according to a second aspect of the present invention, in the semiconductor device of the first aspect, the interlayer insulation film comprises: an etching stopper film; and an upper interlayer insulation film and a lower interlayer insulation film provided on an upper portion and a lower portion of the etching stopper film, respectively, and the fuse is formed in the surface of the interlayer insulation film to a depth limited by a thickness of the upper interlayer insulation film.

Preferably, according to a third aspect of the present invention, in the semiconductor device of the first aspect, the upper interlayer insulation film and the lower interlayer insulation film are silicon oxide films, and the etching stopper film is a silicon nitride film.

Preferably, according to a fourth aspect of the present invention, in the semiconductor device of the first aspect, either of the interconnection layers in the multilevel interconnection layer is provided just under the fuse.

Preferably, according to a fifth aspect of the present invention, in the semiconductor device of the first aspect, a semiconductor element is provided on the semiconductor substrate placed just under the fuse.

According to a sixth aspect of the present invention, a method of manufacturing a semiconductor device including a fuse comprises the steps of: (a) selectively providing a lower interconnection layer on a semiconductor substrate, and providing an interlayer insulation film so as to cover the lower interconnection layer; (b) selectively removing the interlayer insulation film to form, in the interlayer insulation film, first and second holes with a space therebetween each extending through the interlayer insulation film to reach the lower interconnection layer, and to form an opening in a surface of the interlayer insulation film, which as the same form as the fuse and extends between the first and second holes; (c) filling the opening and the first and second holes with a conductor made of the same material to form the fuse and first and second contact portions electrically connected to the fuse as well as being electrically connected to the lower interconnection layer; and (d) selectively forming an upper interconnection layer on the interlayer insulation film by a conductor made of a material different from that of the fuse so as to be electrically connected onto the first and second contact portions.

Preferably, according to a seventh aspect of the present invention, in method of manufacturing the semiconductor device of the sixth aspect, the step (b) comprises the steps of: selectively removing the interlayer insulation film to form the first and second holes which have not extended through having a predetermined depth in the interlayer insulation film; and selectively removing the interlayer insulation film further to form the opening in the surface of the interlayer insulation film between the first and second holes which have not extended through, and simultaneously deepening the first and second holes which have not extended through so that they extend through the interlayer insulation film to reach the lower interconnection layer.

Preferably, according to an eighth aspect of the present invention, in the method of manufacturing the semiconductor device of the sixth aspect, said step (a) comprises the step of: providing a lower interlayer insulation film so as to cover the lower interconnection layer and laminating an etching stopper film and an upper interlayer insulation film in this order on the lower interlayer insulation film, the step (b) comprises the steps of: selectively removing the upper interlayer insulation film to form the first and second holes at a first stage extending through the upper interlayer insulation film to reach the etching stopper film; selectively removing the etching stopper film and deepening the first and second holes at the first stage to form the first and second holes at a second stage extending through the etching stopper film; and selectively removing the upper interlayer insulation film further to form the opening extending through the upper interlayer insulation film between the first and second holes at the second stage, and simultaneously removing the lower interlayer insulation film selectively and deepening the first and second holes at the second stage so that they extend through the interlayer insulation film to reach the lower interconnection layer.

Preferably, according to a ninth aspect of the present invention, in the method of manufacturing the semiconductor device of the eighth aspect, the step (a) includes the steps of: forming the lower interlayer insulation film and the upper interlayer insulation film by silicon oxide films; and forming the etching stopper film by a silicon nitride film, wherein the upper interlayer insulation film is set to have the same thickness as the fuse.

In the semiconductor device of the first aspect, the fuse, extending through the interlayer insulation film, is interposed between the first and second contact portions which are provided with a space therebetween, and is provided in the surface of the interlayer insulation film so as to be electrically connected to the first and second contact portions. The fuse is composed of a conductor made of the same material as the first and second contact portions which differs from a material of the upper interconnection layer. Therefore, a refractory metal such as tungsten can be used as the conductor, enabling to obtain a fuse having high resistivity and being easily fused. Moreover, since the fuse is fused by flowing overcurrent between the first and second contact portions, it can be formed thinner and shorter than the laser-fused fuse, which contributes to miniaturization of the semiconductor device. Further, the fuse needs not be arranged intensively as the laser-fused fuse and may be provided in either of the interlayer insulation films, allowing arrangement flexibility of the fuse to be improved. Furthermore, the fuse is fused by current, so that the fusion does not affect the structure of the lower layers.

In the semiconductor device of the second aspect, the fuse is formed in the surface of the interlayer insulation film to a depth limited by the thickness of the upper interlayer insulation film. Therefore, in the case of providing a plurality of fuses, the depth of the plurality of fuses are unified, enabling to equalize respective values of resistance at the plurality of fuses. Accordingly, it is possible to prevent current required for fusion from varying at the respective fuses and to suppress occurrence of a fuse insufficiently fused.

In the semiconductor device of the third aspect, the upper interlayer insulation film and the lower interlayer insulation layer film are greatly different from the etching stopper film in etching rate, so that the etching stopping function of the etching stopper film is fully exerted.

In the semiconductor device of the fourth aspect, either of the interconnection layers in the multilevel interconnection layer is provided just under the fuse, which contributes to miniaturization of the semiconductor device.

In the semiconductor device of the fifth aspect, the semiconductor element is provided on the semiconductor substrate placed just under the fuse, which contributes to miniaturization of the semiconductor device.

In the method of the manufacturing the semiconductor device of the sixth aspect, it is possible to obtain the semiconductor device comparatively easily having the fuse extending through the interlayer insulation film, being disposed between the first and second contact portions provided with a space therebetween, being provided in the surface of the interlayer insulation film so as to be electrically connected to the first and second contact portion, and being composed of a conductor made of the same material as the first and second contact portions which is different from a material of the upper interconnection layer.

In the method of the seventh aspect, it is possible to form the opening without using the etching stopper film or the like, which allows simplification of the manufacturing steps and enables to obtain a semiconductor device having a comparatively simple structure.

In the method of the eighth aspect, it is possible to obtain a semiconductor device comparatively easily in which the fuse is formed in the interlayer insulation film to a depth limited by the thickness of the upper interlayer insulation film, and in the case of providing a plurality of fuses, the depth of the plurality of fuses are unified so that the respective values of resistance at the fuses are equalized, which prevents current required for fusion from varying at the respective fuses and suppresses occurrence of a fuse insufficiently fused.

In the method of the ninth aspect, the upper interlayer insulation film and the lower interlayer insulation film are greatly different from the etching stopper film in etching rate. Thus, the etching stopping function of the etching stopper film is fully exerted, and it is ensured that the fuse is formed in the upper interlayer insulation film to a depth limited by the thickness of the upper interlayer insulation film.

An object of the present invention is to provide a semiconductor device comprising a fuse for switching connections to a redundant circuit, which is capable of improving arrangement flexibility of the fuse and achieving an increase in the degree of integration.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a semiconductor device according to a preferred embodiment of the present invention.

FIG. 2 is a plan view showing a structure of a fuse of the semiconductor device according to the preferred embodiment.

FIGS. 3 and 4 are sectional views showing manufacturing steps of the semiconductor device according to the preferred embodiment.

FIG. 5 is a plan view showing the structure of the fuse of the semiconductor device according to the preferred embodiment.

FIG. 6 is a sectional view showing a structure of a modification of the semiconductor device according to the preferred embodiment.

FIGS. 7 through 10 are sectional views showing manufacturing steps of the modification of the semiconductor device according to the preferred embodiment.

FIG. 11 is a sectional view showing a structure of a conventional semiconductor device.

### DESCRIPTION OF THE PREFERRED EMBODIMENTS

<A. Device Structure>

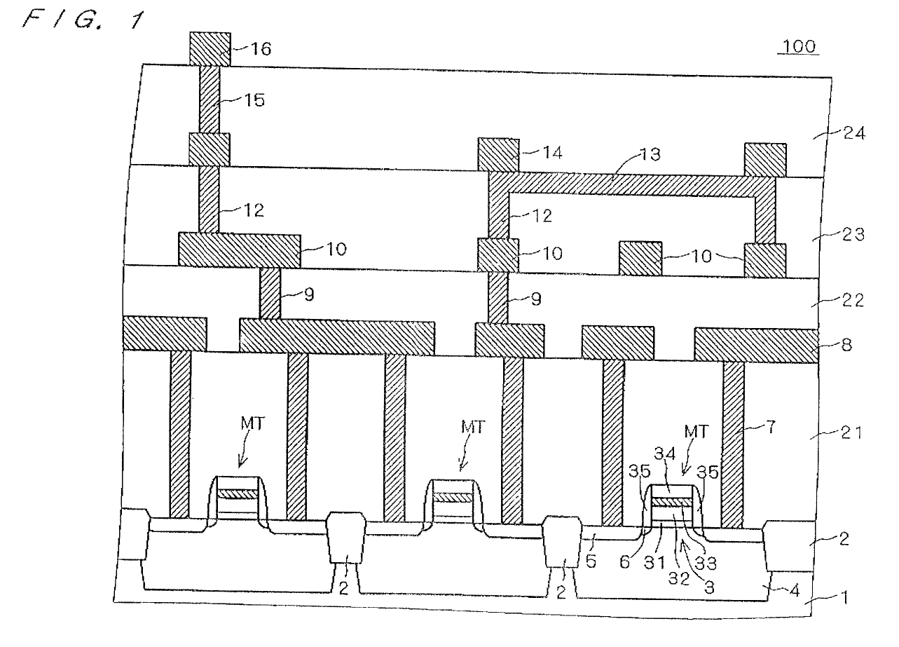

A peripheral circuit portion of a semiconductor device 100 having a multilayered structure is shown in FIG. 1 as a preferred embodiment of the present invention. The multilayered structure means a structure including two or more interconnection layers.

Referring to FIG. 1, a plurality of MOS transistors MT are provided on a semiconductor substrate 1. The MOS transistors MT are arranged on active regions defined as regions of the semiconductor substrate 1 surrounded by isolation films 2, respectively. Each of the MOS transistors MT comprises: a gate electrode 3 including a gate insulating film 31, a polysilicon layer 32, a silicide layer 33, an upper insulation layer 34 which are selectively laminated on the semiconductor substrate 1 in this order and a sidewall insulation film 35 provided on side surfaces of the layers 31, 32, 33 and 34; and a source/drain region 5 formed in a surface of a well region 4 on the outside of two side surfaces of the gate electrode 3; and an LDD (lightly dope drain) region 6.

A first interlayer insulation film 21 is provided so as to entirely cover a main surface of the semiconductor substrate 1, and a plurality of contact portions 7 each extending through the first interlayer insulation film 21 to reach the source/drain region 5 are provided. The contact portions 7 have a structure in which contact holes are filled with a refractory metal such as tungsten.

First interconnection layers 8 composed of aluminum are selectively formed on the first interlayer insulation film 21. The contact portions 7 are connected to a predetermined one of the first interconnection layers 8, respectively.

A second interlayer insulation film 22 is provided so as to cover the first interconnection layers 8, and a plurality of contact portions 9 are provided which extend through the second interlayer insulation film 22 to reach the first interconnection layers 8. The contact portions 9 have a structure in which via holes extending through the second interlayer insulation film 22 are filled with a refractory metal such as tungsten.

Second interconnection layers 10 composed of aluminum are selectively provided on the second interlayer insulation film 22. The contact portions 9 are connected to a predetermined one of the second interconnection layers 10, respectively.

A third interlayer insulation film 23 is provided so as to cover the second interconnection layers 10, and a plurality of contact portions 12 are provided which extend through the third interlayer insulation film 23 to reach the second interconnection layers 10. The contact portions 12 have a structure in which via holes extending through the third interlayer insulation film 23 are filled with a refractory metal such as tungsten. In addition, a fuse 13 is provided between two of the contact portions 12 within the third interlayer insulation film 23 so as to be electrically connected to both of the two contact portions. The fuse 13 is composed of the same refractory metal as the contact portions 12.

Although there is only one fuse 13 shown in FIG. 1, it is needless to say that a plurality of fuses are provided in accordance with the number of spare memory arrays.

Third interconnection layers 14 composed of aluminum are selectively formed on the third interlayer insulation film 23. The plurality of contact portions 12 within the third interlayer insulation film 23 are connected to the third interconnection layers 14, respectively.

A fourth interlayer insulation film 24, which is the uppermost layer, is provided so as to cover the third interconnection layers 14, and a contact portion 15 is provided which extends through the fourth interlayer insulation film 24 to reach the third interconnection layers 14. The contact portion 15 has a structure in which a via hole extending through the fourth interlayer insulation film 24 is filled with a refractory metal such as tungsten.

A fourth interconnection layer 16 composed of aluminum is selectively provided on the fourth interlayer insulation film 24. The contact portion 15 is connected to the fourth interconnection layer 16.

Although illustration of the structure of a memory portion is omitted in FIG. 1, either of the interconnection layers included in the peripheral circuit portion is connected to the memory portion. The memory portion is not limited to a specific structure in the present invention. It may include a stacked capacitor, or a trench type capacitor. The stacked capacitor may include any type of capacitors such as a cylindrical capacitor, a fin capacitor and a thick-film rough-surface capacitor.

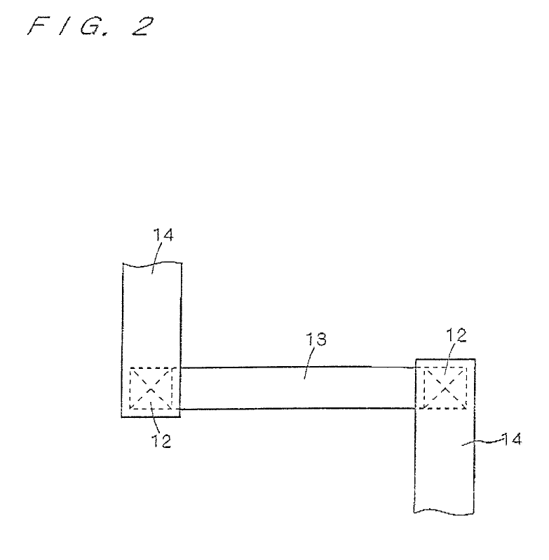

A plane figure of the fuse 13 is shown in FIG. 2. FIG. 2 is a plan view seeing the fuse 13 from above the interlayer insulation film 24. The fuse 13 has the same width as the contact portions 12 and is buried in the third interlayer insulation film 23.

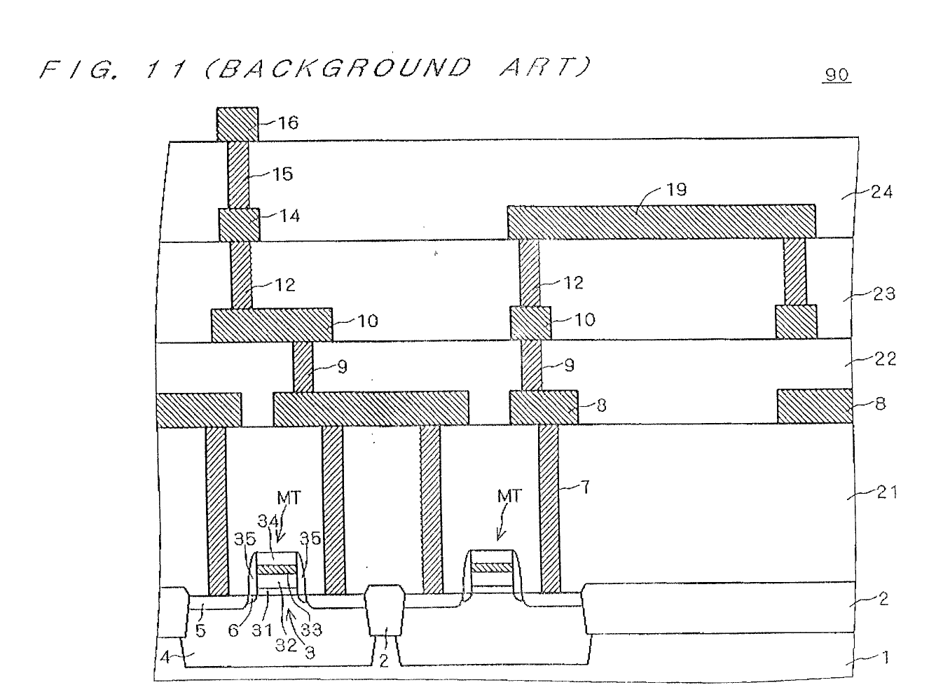

The fuse 13 is a current-fused fuse having a width of approximately 40 nm, which is thinner than the laser-fused fuse 19 having a width of 1-2 μm explained referring to FIG. 11. The length of the fuse 13 is approximately 1-2 μm, not more than one-tenth of the length of the laser-fused fuse 19 (approximately 30 μm).

The fuse 13 is fused by overcurrent flown between two of the contact portions 12 connected to both ends of the fuse 13. Therefore, it is not necessary to provide the fuse 13 intensively as the laser-fused fuse 19, and it may be provided in either of the interlayer insulation films. FIG. 1 exemplifies a structure in which the fuse 13 is provided in the third interlayer insulation film 23.

In FIG. 1, no interconnection layer is provided on the fourth interlayer insulation film 24 corresponding to a top of the fuse 13, however, it is needless to say that a interconnection layer may be provided at this position.

<B. Manufacturing Method>

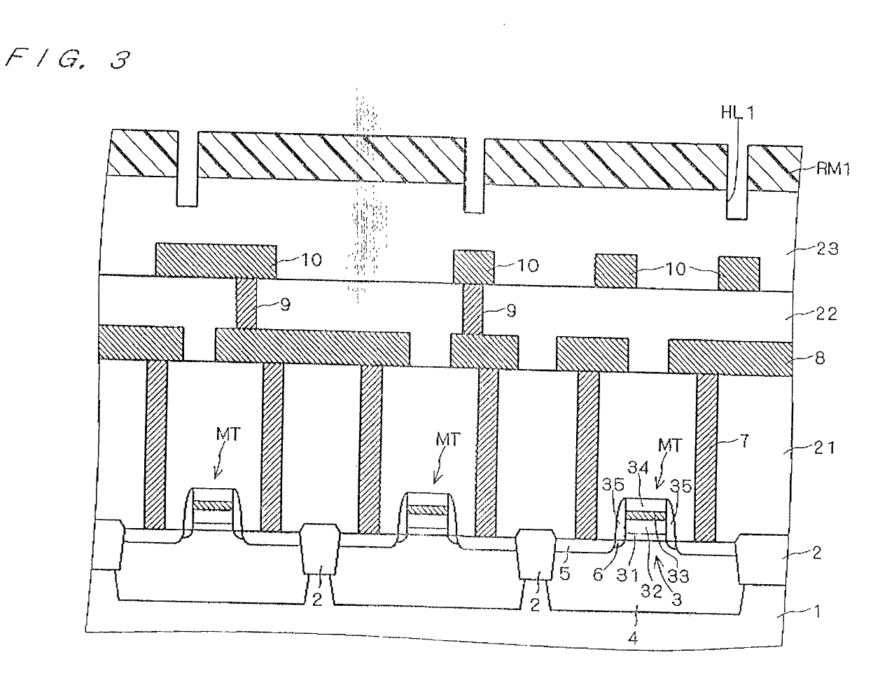

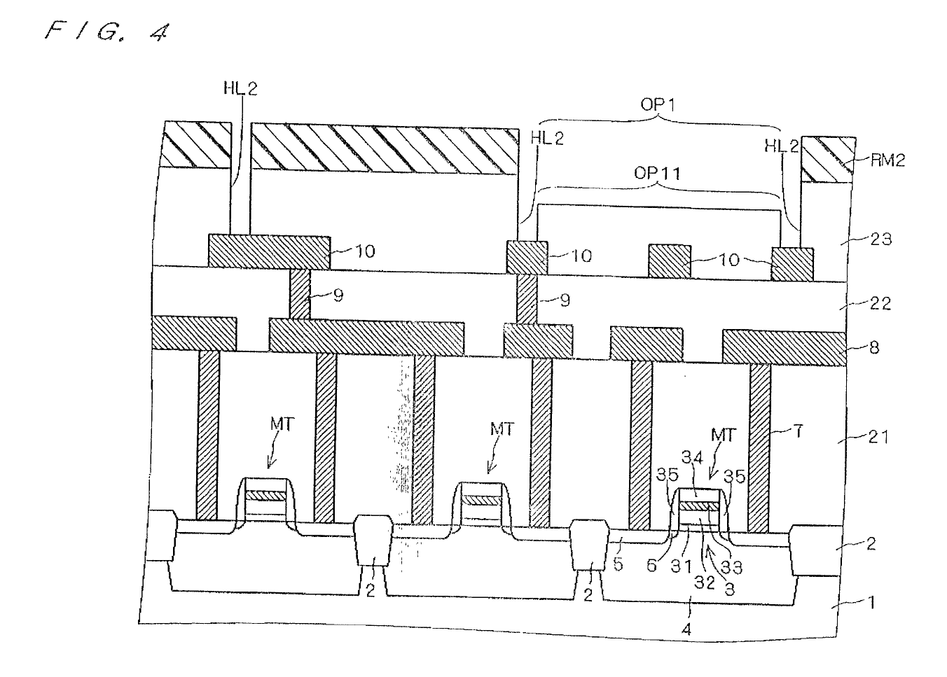

A manufacturing method of the semiconductor device 100 will be described below referring to FIGS. 3 and 4 which are sectional views showing manufacturing steps in order.

First, a conventional manufacturing method is employed in the step shown in FIG. 3 to form the isolation films 2 selectively in a surface of the semiconductor substrate 1 and inject an impurity into a plurality of regions defined by the isolation films 2 to form a plurality of well regions 4. The MOS transistors MT are formed on the plurality of well regions 4, respectively, also by employing a conventional method.

Next, the plurality of MOS transistors MT are covered by a silicon oxide film, for example, to form the first interlayer insulation film 21, and CMP (Chemical Mechanical Polishing) is performed for planarizing. Contact holes are formed which extend through the first interlayer insulation film 21 to reach the source/drain regions 5, respectively. A refractory metal such as tungsten is then filled into the contact holes to form the contact portions 7.

Next, an aluminum layer is formed entirely on the first interlayer insulation film 21 and selectively removed in accordance with a predetermined wiring pattern, thereby forming the first interconnection layers 8. The first interconnection layers 8 are covered by a silicon oxide film, for example, to form the second interlayer insulation film 22 and CMP is performed for planarizing. Then, via holes are formed which extend through the second interlayer insulation film 22 to reach the first interconnection layers 8. A refractory metal such as tungsten is filled into the via holes to form the contact portions 9.

Subsequently, an aluminum layer is formed entirely on the second interlayer insulation film 22 and selectively removed in accordance with a predetermined wiring pattern, thereby forming the second interconnection layers 10. The second interconnection layers 10 are covered by a silicon oxide film, for example, to form the third interlayer insulation film 23 and CMP is performed for planarizing.

Thereafter, a resist mask RM1 is formed on the third interlayer insulation film 23. The resist mask RM1 is used for patterning via holes HL1 (first and second holes which have not extended through) for forming the contact portions 12 by dry etching. Of course, the resist mask RM1 is formed to have openings for patterning the via holes HL1.

The via holes HL1 are formed to a depth of substantially one-third of the thickness of the third interlayer insulation film 23 from a main surface thereof.

After removing the resist mask RM1, a resist mask RM2 is formed on the third interlayer insulation film 23 with an opening OP1 which is to be the fuse 13 having the same form as the fuse 13, in the step shown in FIG. 4. The resist mask RM2 also has openings for forming the contact portions 12.

The resist mask RM2 is then used to form an opening OP11 for forming the fuse 13 by dry etching as well as to form via holes HL2 (first and second holes) reaching the second interconnection layers 10. Accordingly, formation of the opening OP11 and arrival of the via holes HL2 at the second interconnection layers 10 occur simultaneously.

The opening OP11 has a depth of substantially one-third of the thickness of the third interlayer insulation film 23 from the main surface thereof. Assuming that the third interlayer insulation film 23 has a thickness of approximately 1 μm, the opening OP11 has a depth of approximately 300 nm. Further, the second interconnection layers 10 have a thickness of approximately 300 nm, and this also applies to the first interconnection layers 8, third interconnection layers 14 and fourth interconnection layers 16.

Next, the opening OP11 is filled with a refractory metal such as tungsten as the via holes HL2 to form the contact portions 12. Besides, the fuse 13 is formed by the same material as the contact portions 12.

Thereafter, the resist mask RM2 is removed, and an aluminum layer is formed entirely on the third interlayer insulation film 23 and selectively removed in accordance with a predetermined wiring pattern, thereby forming the third interconnection layers 14. The third interconnection layers 14 are covered by a silicon oxide film, for example, to form the fourth interlayer insulation film 24 and CMP is performed for planarizing. Then, a via hole is formed which extends through the fourth interlayer insulation film 24 to reach the third interconnection layer 14. A refractory metal such as tungsten is filled into the via hole to form the contact portion 15.

An aluminum layer is then formed entirely on the fourth interlayer insulation film 24 and selectively removed in accordance with a predetermined wiring pattern, thereby forming the fourth interconnection layers 16. The semiconductor device 100 shown in FIG. 1 is thus obtained.

Referring to the memory portion (not shown), a main structure including a capacitor is formed to be covered by the first interlayer insulation film 21, and a transistor in the memory portion is formed with formation of the MOS transistors MT. Further, the interlayer insulation film 21 may have a structure in which a plurality of interlayer insulation films are laminated in accordance with the structure of the memory portion, however, illustration of such a structure is omitted.

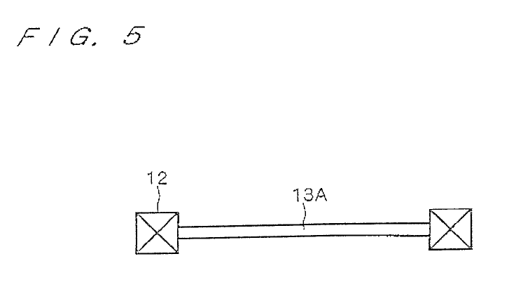

In the above manufacturing method, it has been described that the contact portions 12 are formed at two divided etching stages and the opening OP11 for forming the fuse 13 is simultaneously formed at the second stage. Setting a width of the fuse 13A smaller than that of the contact portions 12 as shown in FIG. 5 enables to form the contact portions 12 and the opening for forming the fuse 13A by one etching.

That is, by setting the fuse 13A to have a width (10-20 nm) ranging substantially from one-half to one-third of the width of the contact portions 12 (approximately 40 nm), the via holes are formed to a depth reaching the second interconnection layers 10 depending on an aspect ratio between the opening width and depth, while the opening for forming the fuse 13A only reaches substantially one-third, or one-half at the maximum, of the thickness of the third interlayer insulation film 23 from the surface thereof, enabling to form an opening having the same sectional figure as the opening OP11 shown in FIG. 4.

The fuse 13A having a smaller width as shown in FIG. 5 is characterized by being easily fused compared to the fuse 13 shown in FIG. 2.

<C. Effect>

In the above-described semiconductor device 100, the fuse 13 fused by current is formed simultaneously at the manufacturing step of the contact portions 12 by the same material as the contact portions 12 that is a refractory metal such as tungsten. Therefore, the fuse 13 is characterized by having resistivity higher than that of each of the interconnection layers composed of aluminum and by being easily fused.

Moreover, since the fuse 13 is fused by current, it can be formed thinner than the laser-fused fuse in not more than one-tenth length of the laser-fused fuse.

Further, the fuse 13 needs not be provided intensively as the laser-fused fuse and may be provided in either of the interlayer insulation films. Thus, arrangement flexibility of the fuse can be enhanced.

Furthermore, since the fuse 13 is fused by current, the fusion does not affect the structure of lower layers, so that a semiconductor element such as a MOS transistor MT as well as the second interconnection layers 10 and first interconnection layers 8 can be formed below the fuse 13 as shown in FIG. 1. Therefore, it is possible to contribute to an improved degree of integration of a semiconductor device.

<D. Modification>

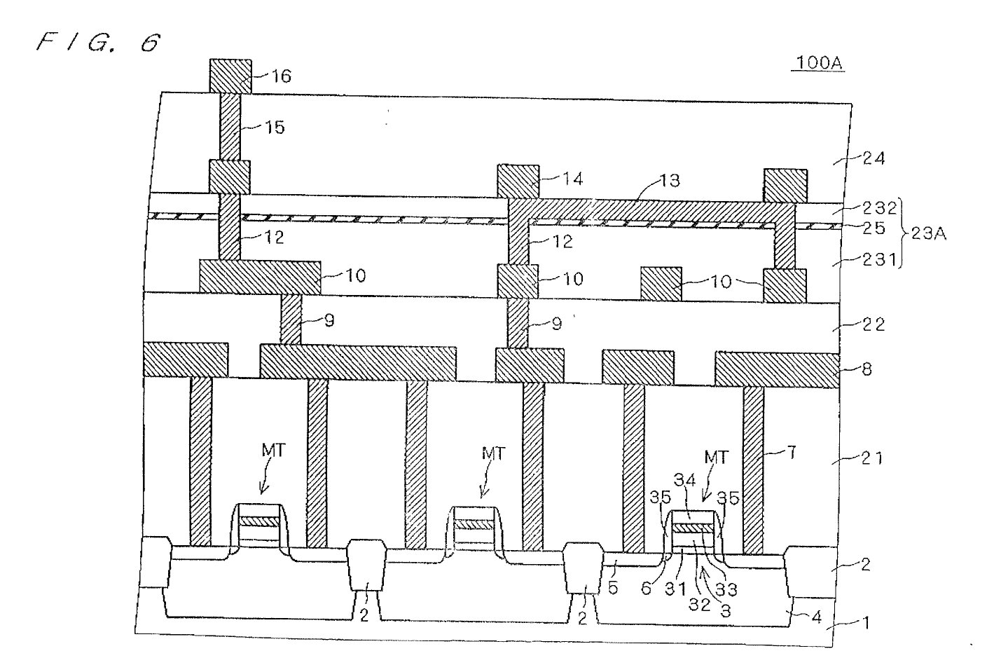

In the semiconductor device 100 explained referring to FIG. 1, the etching of the contact portions 12 is carried out at two stages, and the opening OP11 for forming the fuse 13 is formed simultaneously at the second stage, thereby limiting the depth of the fuse 13. As in a semiconductor device 100A shown in FIG. 6, however, the depth of the fuse 13 may be limited by providing an etching stopper film 25.

In the semiconductor device 100A shown in FIG. 6, a third interlayer insulation film 23A formed by a lower interlayer insulation film 231, an upper interlayer insulation film 232 and the etching stopper film 25 interposed therebetween is provided in place of the third interlayer insulation film 23.

The etching stopper film 25 is composed of a silicon nitride film (Si₃N₄) having a thickness of 10 to 50 nm, for example, and offers resistance to etching of the lower interlayer insulation film 231 and upper interlayer insulation film 232 which are silicon oxide films.

Consequently, the depth of the fuse 13 is limited by the thickness of the upper interlayer insulation film 232, i.e., the depth of the etching stopper film 25. Thus, the depth of a plurality of fuses 13 are equalized, enabling to equalize respective values of electric resistance at the plurality of fuses 13. Accordingly, it is possible to prevent current required for fusion from varying at the respective fuses 13 and to suppress occurrence of a fuse insufficiently fused.

The same reference characters are used in FIG. 6 for the same structure as the semiconductor device 100 explained in reference to FIG. 1, and a repeated explanation is omitted here.

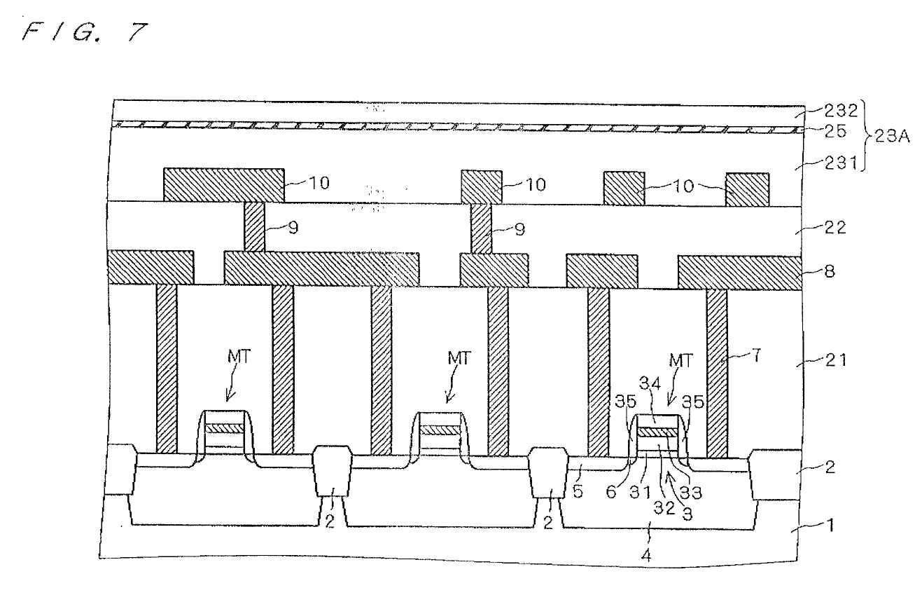

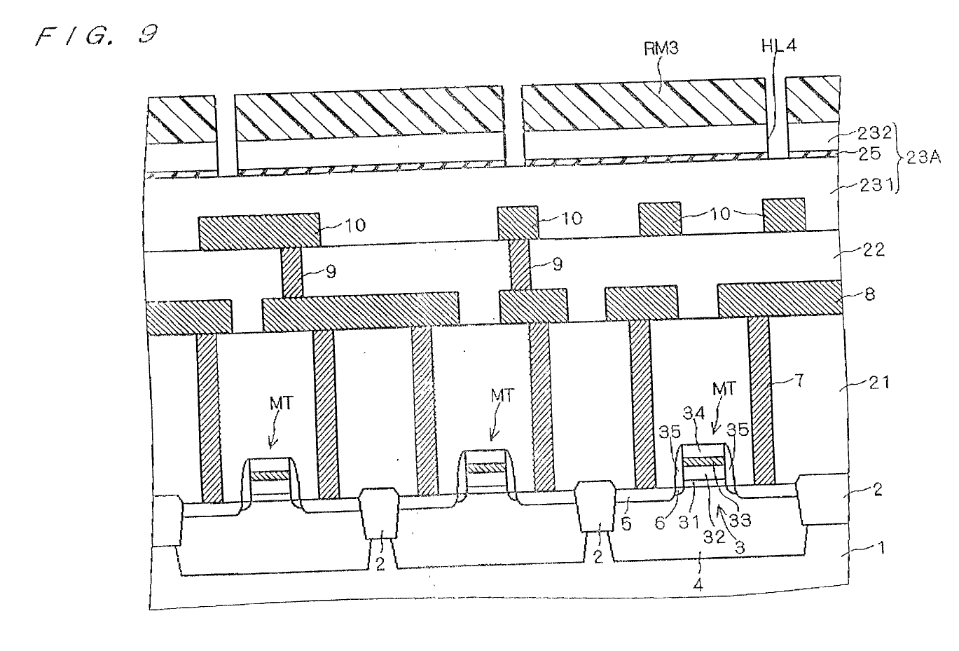

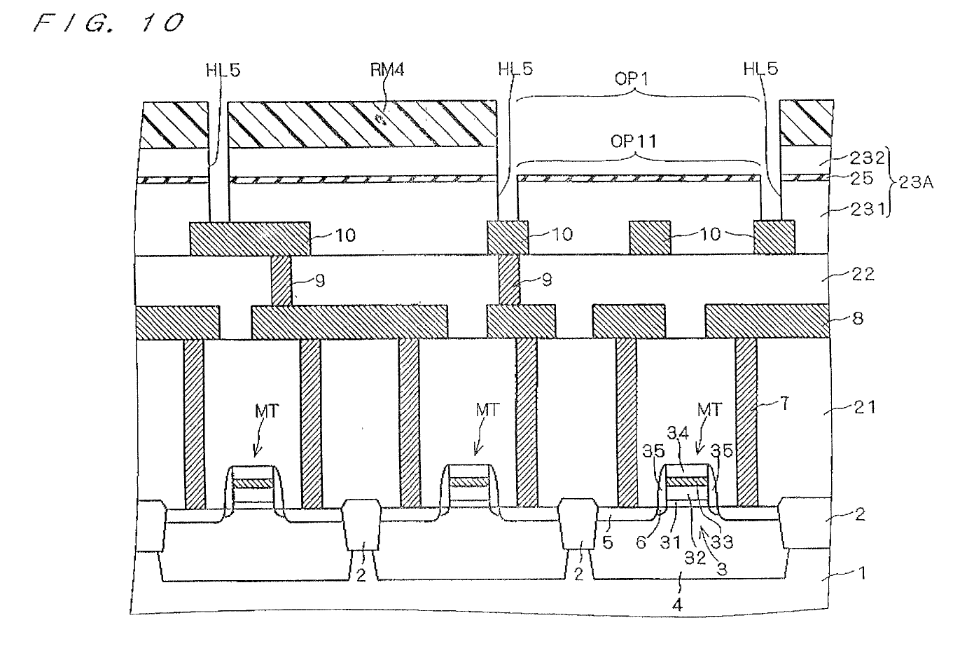

Referring now to FIGS. 7 through 10, a method of manufacturing the semiconductor device 100A will be described.

First, through steps similar to those in the method of manufacturing the semiconductor device 100 explained in reference to FIG. 3, the second interconnection layers 10 are formed on the second interlayer insulation film 22 and are thereafter covered by a silicon oxide film, for example, so that the lower interlayer insulation film 231 is formed.

Subsequently, the etching stopper film 25 composed of a silicon nitride film in a thickness of 10 to 50 nm is formed on the lower interlayer insulation film 231. The upper interlayer insulation film 232 is then formed on the etching stopper film 25. The upper interlayer insulation film 232 is set in a thickness of approximately 300 nm in accordance with the thickness of the fuse 13.

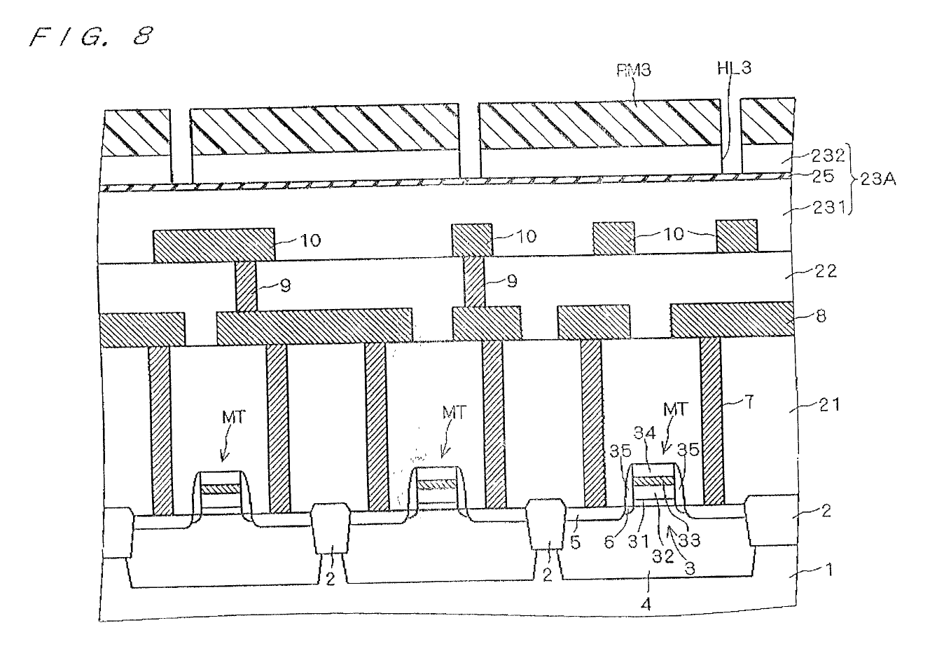

Next, in the step shown in FIG. 8, a resist mask RM3 is formed on the upper interlayer insulation film 232. The resist mask RM3 is used to pattern via holes HL3 (first and second holes at a first stage) for forming the contact portions 12 by dry etching. It is needless to say that the resist mask RM3 is formed to have openings for patterning the via holes HL3.

The above etching is intended for the upper interlayer insulation film 232. A dry etching is carried out using C₄F₈, for example, so that the etching stops at the etching stopper film 25.

Next, the resist mask RM3 is used to each the etching stopper film 25 for deepening the via holes HL3 to form via holes HL4 (first and second holes at a second stage). A dry etching is carried out here using CHF₃, for example, so that the etching stops at the lower interlayer insulation film 231.

After removing the resist mask RM3, a resist mask RM4 is formed on the upper interlayer insulation film 232 with an opening OP1 which is to be the fuse 13 having the same form as the fuse 13. The resist mask RM4 has other openings for forming the contact portions 12.

The resist mask RM4 is used to form the opening OP11 for forming the fuse 13 by dry etching and to form via holes HL5 (first and second holes) reaching the second interconnection layers 10. Thus, formation of the opening OP11 and arrival of the via holes HL5 at the second interconnection layers 10 occur simultaneously.

The above etching is intended for the upper interlayer insulation film 232, and the etching stops at the etching stopper film 25, so that the depth of the opening OP11 is equalized to the thickness of the upper interlayer insulation film 232. On the other hand, the etching proceeds in the via holes HL4, and the via holes HL5 reaching the second interconnection layers 10 is formed.

Next, a refractory metal such as tungsten is filled into the opening OP11 as the via holes HL5 to form the contact portions 12, and the fuse 13 is formed by the same material as the contact portions 12.

Thereafter, the semiconductor device 100A shown in FIG. 6 can be obtained through steps similar to those in the method of manufacturing the semiconductor device 100 explained referring to FIG. 3.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate;
a multilevel interconnection layer provided on said semiconductor substrate;
an interlayer insulation film provided between a lower interconnection layer and an upper interconnection layer in said multilevel interconnection layer;
first and second contact portions extending through said interlayer insulation film and electrically connecting said lower interconnection layer and said upper interconnection layer; and
a fuse interposed between said first and second contact portions and provided in a surface of said interlayer insulation film so as to be electrically connected to said first and second contact portions, said fuse being composed of a conductor made of the same material as said first and second contact portions which differs from a material of said upper interconnection layer, said fuse being fusible by flowing overcurrent between said first and second contact portions.

2. The semiconductor device according to claim 1, wherein
said interlayer insulation film comprises:
an etching stopper film; and
an upper interlayer insulation film and a lower interlayer insulation film provided on an upper portion and a lower portion of said etching stopper film, respectively, and
said fuse is formed in said surface of said interlayer insulation film to a depth limited by a thickness of said upper interlayer insulation film.

3. The semiconductor device according to claim 2, wherein
said upper interlayer insulation film and said lower interlayer insulation film are silicon oxide films, and
said etching stopper film is a silicon nitride film.

4. The semiconductor device according to claim 1, wherein
either of interconnection layers in said multilevel interconnection layer is provided just under said fuse.

5. The semiconductor device according to claim 1, wherein
a semiconductor element is provided on said semiconductor substrate placed just under said fuse.

6. A method of manufacturing a semiconductor device including a fuse, comprising the steps of:
(a) selectively providing a lower interconnection layer on a semiconductor substrate, and providing an interlayer insulation film so as to cover said lower interconnection layer;
(b) selectively removing said interlayer insulation film to form, in said interlayer insulation film, first and second holes with a space therebetween each extending through said interlayer insulation film to reach said lower interconnection layer, and to form an opening in a surface of said interlayer insulation film, which has the same form as said fuse and extends between said first and second holes;
(c) filling said opening and said first and second holes with a conductor made of the same material to form said fuse and first and second contact portions electrically connected to said fuse as well as being electrically connected to said lower interconnection layer; and
(d) selectively forming an upper interconnection layer on said interlayer insulation film by a conductor made of a material different from that of said fuse so as to be electrically connected onto said first and second contact portions.

7. The method of manufacturing a semiconductor device according to claim 6, wherein
said step (b) comprises the steps of:
selectively removing said interlayer insulation film to form said first and second holes which have not extended through having a predetermined depth in said interlayer insulation film; and
selectively removing said interlayer insulation film further to form said opening in said surface of said interlayer insulation film between said first and second holes which have not extended through, and simultaneously deepening said first and second holes which have not extended through so that they extend through said interlayer insulation film to reach said lower interconnection layer.

8. The method of manufacturing a semiconductor device according to claim 6, wherein
said step (a) comprises the step of:
providing a lower interlayer insulation film so as to cover said lower interconnection layer and laminating an etching stopper film and an upper interlayer insulation film in this order on said lower interlayer insulation film,
said step (b) comprises the steps of:
selectively removing said upper interlayer insulation film to form said first and second holes at a first stage extending through said upper interlayer insulation film to reach said etching stopper film;
selectively removing said etching stopper film and deepening said first and second holes at said first stage to form said first and second holes at a second stage extending through said etching stopper film; and
selectively removing said upper interlayer insulation film further to form said opening extending through said upper interlayer insulation film between said first and second holes at said second stage, and simultaneously removing said lower interlayer insulation film selectively and deepening said first and second holes at said second stage so that they extend through said interlayer insulation film to reach said lower interconnection layer.

9. The semiconductor device according to claim 8, wherein
said step (a) includes the steps of:
forming said lower interlayer insulation film and said upper interlayer insulation film by silicon oxide films; and
forming said etching stopper film by a silicon nitride film, wherein
said upper interlayer insulation film is set to have the same thickness as said fuse.
